(19) United States
(12) Patent Application Publication
(10) Pub. No.: US 2023/0024132 A1
(43) Pub. Date: Jan. 26, 2023

(54) SUBSTRATE PROCESSING APPARATUS AND METHOD

(71) Applicant: Picosun Oy, Espoo (FI)

(72) Inventor: Marko PUDAS, Masala (FI)

(73) Assignee: Picosun Oy, Espoo (FI)

(21) Appl. No.: 17/791,075

(22) PCT Filed: Dec. 22, 2020
(86) PCT No.: PCT/FI2020/050862

§ 371 Date: Jul. 6, 2022

(30) Foreign Application Priority Data
Jan. 10, 2020 (FI) 20205024

(51) Int. Cl. C23C 16/455; C23C 16/44; C23C 16/458

(52) U.S. Cl. CPC C23C 16/45544; C23C 16/4412; C23C 16/45591; C23C 16/4584

(57) ABSTRACT

A substrate processing apparatus, including a reaction chamber enclosing a substrate processing space and a chemical exit space, further including a substrate support. The apparatus is configured to direct a chemical flow into the substrate processing space, to expose a substrate supported by the substrate support to surface reactions, therefrom via a first gap into a first expansion volume of the chemical exit space, and therefrom via a second gap towards an exhaust pump, the apparatus being configured to provide the chemical flow with a choked flow effect in at least one of the first and second gaps.

### FIELD

The aspects of the disclosed embodiments generally relates to substrate processing methods and apparatus. More particularly, but not exclusively, the disclosed embodiments relate to atomic layer deposition (ALD) reactors.

### BACKGROUND

This section illustrates useful background information without admission of any technique described herein representative of the state of the art.

In chemical deposition methods, such as atomic layer deposition (ALD), surface reactions on a substrate can be obtained by exposing the substrate to precursor chemicals, which produce a thin-film deposit on the substrate surface. Deploying a gas source for deposition, however, may cause turbulent gas flow creating backflow and undesired chemical reactions in a reaction chamber.

### SUMMARY

The aspects of the disclosed embodiments are directed to cope with the above-identified problem or with other problem(s) or at least to provide an alternative solution to existing technology, for instance aiming to minimize the backflow of chemicals in a substrate processing apparatus.

Choked flow of a gas takes place when the gas at a certain pressure and temperature flows through a restrictor in a passageway and enters a space with decreased pressure. When entering the restricted area, the pressure and density of the gas decreases, whereas its velocity increases up to sonic speed. The pressure conditions influence the mass flow rate of the gas, which at sonic conditions becomes independent of the downstream pressure in the system. In certain embodiments, the mass flow rate of the gas at sonic conditions depends typically on the cross section of the restricted area and the upstream pressure.

In certain embodiments, when deploying a choked flow restrictor in a passageway of a vacuum deposition equipment, the pressure changes downstream from the restrictor do not influence the flow rate of the gases above the restrictor. In certain embodiments, the backflow of chemicals into unwanted directions can also be prevented.

According to a first example aspect of the disclosed embodiments there is provided a substrate processing apparatus, comprising:

a reaction chamber, enclosing a substrate processing space and a chemical exit space; and

a substrate support;

the apparatus being configured to direct a chemical flow into the substrate processing space, to expose a substrate supported by the substrate support to surface reactions, therefrom via a first gap into a first expansion volume of the chemical exit space, and therefrom via a second gap towards an exhaust pump, the apparatus being configured to provide the chemical flow with a choked flow effect in at least one of the first and second gaps.

In certain embodiments, the chemical exit space comprises a second expansion volume, the apparatus being configured to direct the chemical flow from the first expansion volume via the second gap into the second expansion volume.

Accordingly, in certain embodiments, the first gap separates the substrate processing space and the first expansion volume, and the second gap separates the first expansion volume and the second expansion volume.

In certain embodiments, the apparatus is configured to remove the chemical flow from the reaction chamber into a reaction chamber outlet channel.

In certain embodiments, the reaction chamber outlet channel begins from the second expansion volume.

In certain embodiments, the form of the gaps is a closed curve, for example a circle or an annular form. In certain embodiments, the form of the gap(s) is a regular closed curve, in other embodiments irregular closed curve forms may be used.

In certain embodiments, the first gap substantially resides in the plane defined by an upper surface of the substrate holder. Accordingly, in certain embodiments, the first gap either resides or nearly resides in said plane. In certain embodiments, the second gap resides downstream from the first gap.

In certain embodiments, the entry opening from substrate processing space into the chemical exit space is different on different sides of the substrate support. In certain embodiments, this depends on the direction of the chemical input arriving to the substrate processing space.

In certain embodiments, the chemical exit space comprises more than two expansion volumes. In certain embodiments, the chemical exit space comprises more than two gaps. In certain embodiments, the apparatus is configured to provide the chemical flow with a choked flow effect in two or more than two gaps in the chemical exit space.

In certain embodiments, the reaction chamber is defined by a reaction chamber wall. In certain embodiments, the reaction chamber wall is heated. In certain embodiments, the substrate support is heated.

In certain embodiments, the substrate support is rotationally symmetric about its rotational axis. In certain embodiments, the substrate support is circular shaped from above. In certain embodiments, the substrate support or its top part is of cylindrical shape. In certain embodiments, the substrate support or its top part is shaped as a truncated cone, or as an upside-down truncated cone. In certain embodiments, the design of the substrate support described herein is to enable uniform chemical flow to the chemical exit space.

In certain embodiments, the vertical position of the substrate support is adjustable.

In certain embodiments, the substrate support is configured to adjust vertically the substrate position to enable loading and unloading of the substrate into the substrate processing space.

In certain embodiments, the substrate support has lifter pins to adjust the substrate vertically, to facilitate loading of the substrate into, and unloading of the substrate from the substrate processing space.

In certain embodiments, the apparatus is configured to provide a chemical flow route into a volume in between the substrate support and an inner surface of the reaction chamber, the inner surface of the reaction chamber and the substrate support delimiting a space forming at least one of the expanding volumes.

In certain embodiments, instead of being of a regular cylindrical shape, the reaction chamber inner wall is uneven, comprising, for example, an undulating, zigzag and/or stepped form, thereby forming the expansion space(s) and gap(s) against the surface of the substrate support. In certain embodiments, the substrate support comprises a substrate holder, forming at least the top part of the substrate support, and a base part below the substrate holder. In certain embodiments, the base part extends downwards, or parallel to the vertical rotational axis of the substrate support, from the top part.

In certain embodiments the side surface of the substrate support is uneven, comprising, for example, an undulating, zigzag and/or stepped form, thereby forming the expansion space(s) and gap(s) against the inner surface of the reaction chamber.

In certain embodiments, inner corners of the inner wall of the reaction chamber and/or corners of the substrate support are rounded, to prevent turbulent chemical flow.

In certain alternative embodiments circular partitions extend from the reaction chamber inner wall, forming the expansion spaces and gaps against the surface of the substrate support.

In certain embodiments, at least one of the gaps is formed in between the substrate support and the reaction chamber inner surface.

In certain embodiments, the first gap is configured to provide the chemical flow with a choked flow effect.

In certain embodiments, the second gap is configured to provide the chemical flow with a choked flow effect.

In certain embodiments, both the first and second gap are configured to provide the chemical flow with a choked flow effect.

In certain embodiments, the first gap has an aspect ratio of at least 2:1 (expansion volume width: gap width). In certain embodiments, the aspect ratio of at least 2:1 facilitates a chemical flow through the first gap with a choked flow effect.

In certain embodiments, the first gap and/or the second gap has an aspect ratio of at least 2:1 (expansion volume width: gap width). In certain embodiments, the aspect ratio of at least 2:1 facilitates a chemical flow through the gap(s) concerned with a choked flow effect.

In certain embodiments, the apparatus comprises at least one circular chemical feed inlet configured to inject inert and/or reactive chemical into the chemical exit space. In certain embodiments, the at least one circular chemical feed inlet is incorporated in the wall(s) of the reaction chamber.

In certain embodiments, the at least one circular chemical feed inlet is configured to inject inert and/or reactive chemical into the chemical exit space to direct chemicals towards the outlet channel.

In certain embodiments, the apparatus comprises the at least one chemical feed inlet, arranged immediately downstream from one of the said gaps, to prevent backflow of chemicals in the chemical exit space.

In certain embodiments, the chemical feed inlet is arranged directly downstream from the gap, at an inner corner of the gap.

In certain embodiments, a reaction chamber outlet channel comprises two separate branches. In certain embodiments, the apparatus comprises a pump or a turbomolecular pump in each two separate branches of the outlet channel, to exhaust gases from the reaction chamber.

Accordingly, in certain embodiments, the reaction chamber outlet channel branches into two separate branches. In certain embodiments, both branches comprise their own pumps.

In certain embodiments, the apparatus comprises a valve in the outlet channel, configured to control flow of chemicals into the two separate branches.

In certain embodiments, the valve is a 3-way valve. In certain embodiments, the said valve in the outlet channel controls the flow of chemicals towards the two pumps or turbomolecular pumps.

In certain embodiments, the apparatus comprises at least one chemical trap in the outlet channel downstream from the pumps or turbomolecular pumps. In certain embodiments, to trap is to collect unreacted chemical precursor.

In certain embodiments, the apparatus comprises a vacuum pump in one of the separate branches of the outlet channel, downstream from the two pumps (or turbomolecular pumps), or preferably, comprises a vacuum pump in each separate branch of the outlet channel, downstream from the respective pump.

In certain embodiments, at least one of the separate branches or both branches comprise a turbomolecular pump followed by a vacuum pump.

In certain embodiments, the apparatus comprises a joined exhaust line to mix the flow of chemicals from the two separate branches of the outlet channel.

In certain embodiments, the apparatus comprises a further restrictor in the outlet channel enabling a chemical flow with a choked flow effect. In certain embodiments, the apparatus comprises a further discharge (or exhaust) pump after the choked flow restrictor in the outlet channel or in the joined exhaust line. The discharge pump may be close to atmospheric pressure or substantially in ambient pressure.

In certain embodiments, the substrate support is arranged to cut off the chemical flow towards the exhaust pump. In certain embodiments, the substrate support is arranged in a position where the chemical flow route between the substrate processing space and the chemical exit space is cut off. In certain embodiments, the substrate support is arranged to cut off the chemical flow into the chemical exit space or into the reaction chamber outlet channel by means of moving the substrate support, for example, vertically.

In certain embodiments, the apparatus is configured to close the second gap by the substrate holder. In certain embodiments, the substrate holder is configured to be lowered to close the second gap.

In certain embodiments, the reaction chamber chemical exit space has an opening for chemical outlet at its bottom part, for example, at the bottom of the bottom part or on a side of the bottom part. In certain embodiments, the opening for chemical outlet resides symmetrically in the center of the bottom of the bottom part.

In certain embodiments, the apparatus comprises an outer chamber (vacuum chamber) at least partly surrounding the reaction chamber, or enclosing at least partly the reaction chamber. In certain embodiments, an intermediate space in between the reaction chamber and outer chamber walls is provided with an inlet and an outlet to purge the intermediate space by inactive gas.

In certain embodiments, the apparatus is configured to expose the substrate to sequential self-saturating (self-limiting) surface reactions.

According to a second example aspect of the disclosed embodiments there is provided a method in a substrate processing apparatus having a reaction chamber enclosing a substrate processing space and a chemical exit space, comprising:

directing a chemical flow into the substrate processing space, to expose a substrate supported by a substrate support to surface reactions,

directing the chemical flow therefrom via a first gap into a first expansion volume of the chemical exit space, and therefrom via a second gap towards an exhaust pump; and

providing the chemical flow with a choked flow effect in at least one of the first and second gaps.

In certain embodiments, the method comprises exposing the substrate to sequential self-saturating (self-limiting) surface reactions.

The embodiments and their combinations presented in the context of the apparatus aspect apply to the method aspect as well. Accordingly, they are not repeated herein.

According to a yet another example aspect there is provided an apparatus and corresponding method with disclosed elements but without the choked flow effect in any of the gap(s).

According to a yet another example aspect there is provided an apparatus and corresponding method with disclosed elements with the first gap but without any of the further gaps (with or without the choked flow effect).

Different non-binding example aspects and embodiments have been illustrated in the foregoing. The above embodiments are used merely to explain selected aspects or steps that may be utilized in implementations of the present disclosure. Some embodiments may be presented only with reference to certain example aspects. It should be appreciated that corresponding embodiments apply to other example aspects as well. Any appropriate combinations of the embodiments may be formed.

### BRIEF DESCRIPTION OF THE DRAWINGS

The disclosed embodiments will now be described, by way of example only, with reference to the accompanying drawings, in which:

FIG. 1 shows a schematic cross section of a reaction chamber of a substrate processing apparatus in accordance with certain embodiments;

FIG. 2 shows another possible schematic cross section of a reaction chamber of a substrate processing apparatus in accordance with certain embodiments;

FIG. 3 shows a perspective view of certain parts of an apparatus in accordance with certain embodiments;

FIG. 4 shows a schematic cross section of a reaction chamber of a substrate processing apparatus in accordance with certain embodiments;

FIG. 5 shows a schematic drawing of the reaction chamber and a chemical outlet line arrangement in accordance with certain embodiments;

FIG. 6 shows a further schematic drawing of a chemical outlet line arrangement in accordance with certain embodiments; and

FIG. 7 shows a perspective view of certain parts of an apparatus in accordance with certain embodiments.

### DETAILED DESCRIPTION

In the following description, Atomic Layer Deposition (ALD) technology is used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD one or more of the deposition steps can be assisted by providing required additional energy for surface reactions through plasma or photon in-feed, respectively. Or one of the reactive precursors can be substituted by energy (such as mere photons), leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the disclosed embodiments are not limited to ALD technology, but it can be exploited in a wide variety of substrate processing apparatuses, for example, in Chemical Vapor Deposition (CVD) reactors, or in etching reactors, such as in Atomic Layer Etching (ALE) reactors.

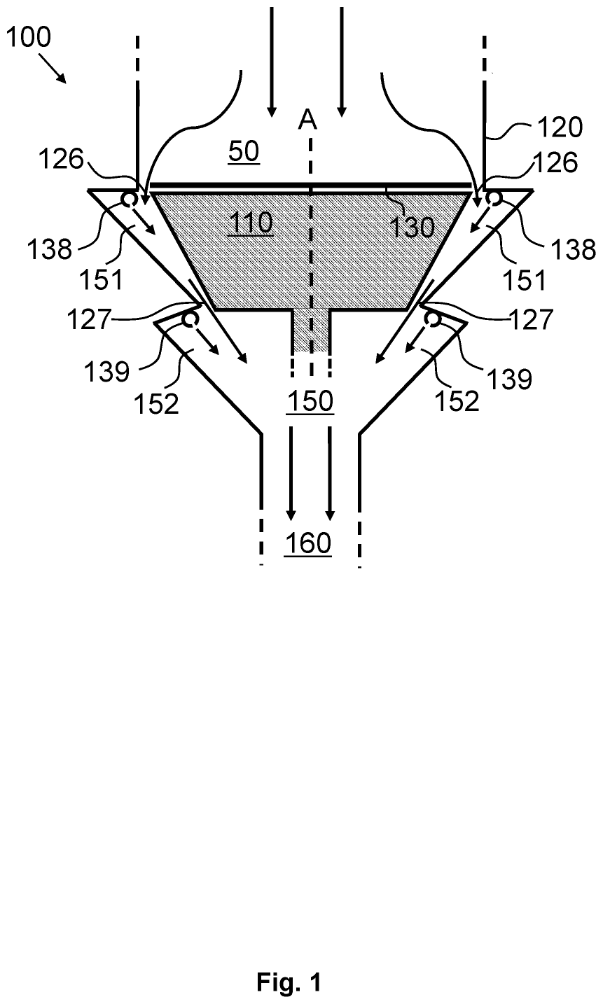

FIG. 1 shows a schematic cross section of a reaction chamber of a substrate processing apparatus in accordance with certain embodiments. An apparatus 100 is a substrate processing apparatus which may be, for example, an ALD reactor or an ALE reactor.

The apparatus 100 comprises a reaction chamber 120, which encloses a substrate processing space 50, a chemical exit space 150, and a substrate support 110, on which a substrate 130 is supported and processed in the substrate processing space 50.

In certain embodiments, the chemical exit space 150 comprises a first expansion volume 151 and a second expansion volume 152, wherein a first gap 126 separates the substrate processing space 50 and the first expansion volume 151, and a second gap 127 separates the first expansion volume 151 and the second expansion volume 152. In certain embodiments, the gaps 126, 127 and expansion spaces 151, 152 are formed in a space between a substrate support and the reaction chamber 120 inner wall, the substrate support 110 comprising at least the substrate holder and a substrate support base part. The substrate support base part may extend vertically from the substrate support 110, parallel to axis A.

In certain embodiments, the reaction chamber 120 inner wall has a circular shape from above. In certain embodiments, from a horizontal perspective, the reaction chamber 120 inner wall, or the side surface of the substrate support 110, or both, may be uneven shaped, thereby forming the expansion spaces 151, 152 and gaps 126, 127 in between each other, and improving the unidirectional flow of chemicals through the space towards a reaction chamber outlet channel 160. This shape of the said chemical pathway also reduces turbulent flow of chemicals therein. From the horizontal perspective, the shape of the reaction chamber 120 inner wall, or the substrate support 110 or both, may be, for example, undulating, zigzag or stepped. In certain embodiments, the substrate support 110 is of cylindrical shape. In certain embodiments, the substrate support 110 may be shaped as a truncated cone or as an upside down oriented truncated cone. In certain embodiments, the substrate support 110 may be shaped, when viewed from above, circle or oval. In certain embodiments, when viewed from above, the substrate support 110 is located in the center of the reaction chamber 120. In certain embodiments, when viewed from above, the substrate support 110 is located in the center off the axis A. In certain embodiments, the first gap 126 is provided around the substrate support 110. In certain embodiments, the first gap is of different width on different sides of the substrate support 110.

In certain embodiments, multiple substrate supports 110, which are separated from each other or merged together, are located in the reaction chamber 120.

The apparatus 100, as depicted in FIGS. 1, 2 and 4, optionally comprises at least one circular chemical feed inlet 138, 139 configured to inject a directed flow of inert and/or reactive chemical into the chemical exit space 150. In certain embodiments, the at least one circular chemical feed inlet 138, 139 is arranged to line the inner surface of the reaction chamber 120, along its circumference. The at least one circular chemical inlet 138, 139 may be arranged directly downstream from, at the corner of, one of the said gaps 126, 127, and it may be configured to inject chemical into the expansion volume 151, 152 in a manner that improves the exhaust of chemicals therefrom. In certain embodiments, the said at least one circular chemical feed inlet 138, 139 is configured to prevent backflow and turbulence of chemicals in the chemical exit space 150. In certain embodiments the at least one circular chemical feed inlet 138, 139 may eject inert chemical through directed chemical flow, and prevent turbulent gas flow in the chemical exit space 150. In certain embodiments, the at least one circular chemical feed inlet 138, 139 may eject reactive precursor chemical that interacts and reacts with another precursor chemical arriving to the expansion volume 151, 152 through the gap 126, 127, thereby functioning as an afterburner.

Due to large pressure differences which can be generated between the substrate processing space 50 and the outlet channel 160, the gaps 126, 127 can be surrounded by pressure resulting in an adequate minimum pressure ratio, facilitating the formation of a chemical flow with a choked flow effect in the said gaps 126, 127. In certain embodiments, the minimum pressure ratio required for choked flow to occur is 1.7:1 (upstream:downstream).

In certain embodiments, the apparatus 100 comprises an outer chamber (vacuum chamber, not shown) at least partly surrounding the reaction chamber 120, or enclosing at least partly the reaction chamber 120. In certain embodiments, an intermediate space in between the reaction chamber and outer chamber walls is provided with an inlet and an outlet to purge the intermediate space by inactive gas.

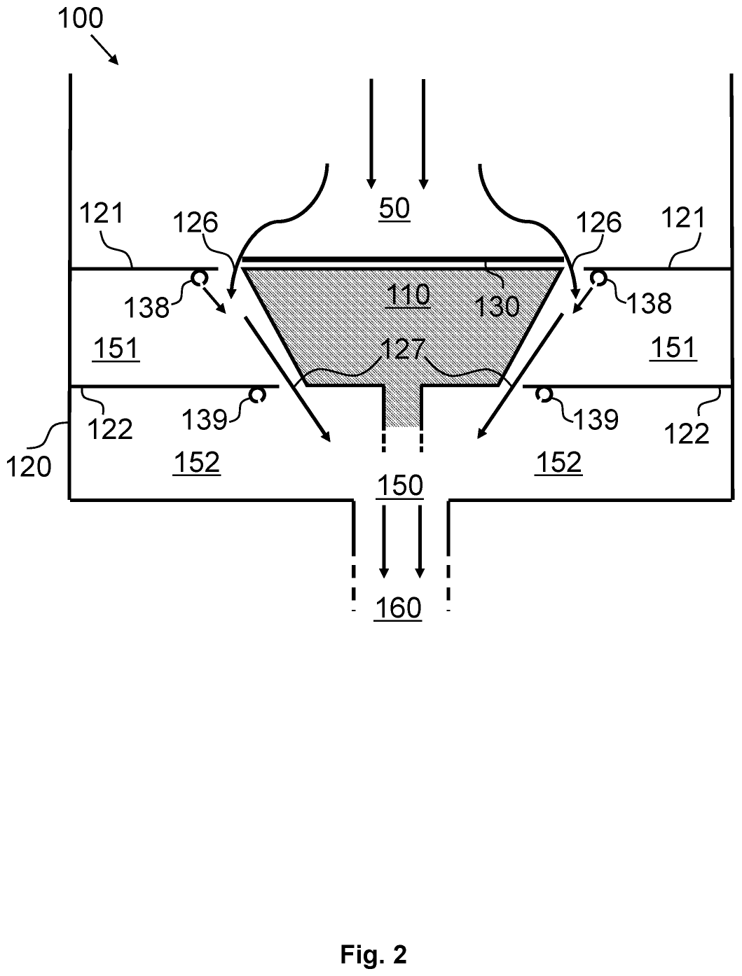

In certain embodiments, as depicted in FIG. 2 as a schematic cross section of a reaction chamber of a substrate processing apparatus 100, circular partitions 121, 122 may extend from the reaction chamber 120 inner side wall, thereby forming the said expansion spaces 151, 152 and gaps 126, 127 against the surface of the substrate support 110.

In certain embodiments, the edges of the reaction chamber 120 inner wall, or substrate support 110, or both, may be rounded, which reduces turbulence in the chemical flow.

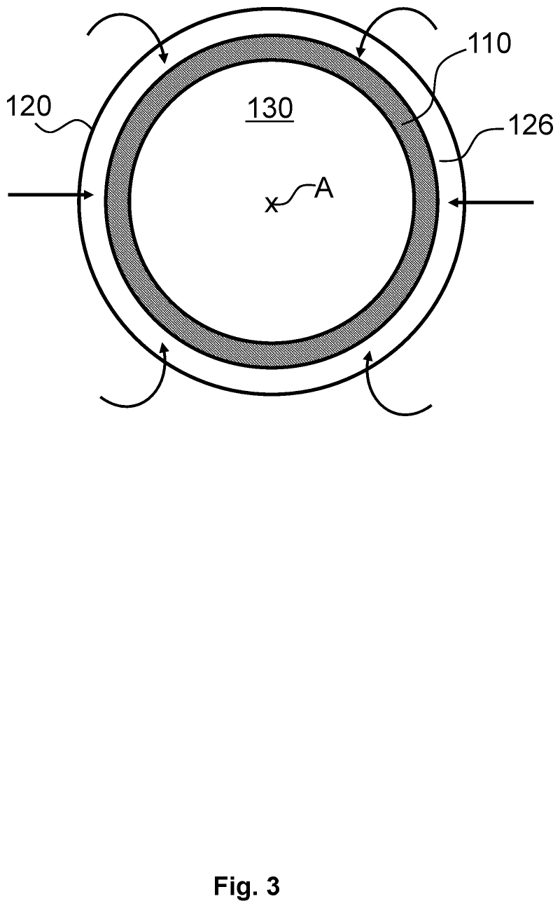

FIG. 3 shows a perspective view of certain parts of an apparatus in accordance with certain embodiments. In certain embodiments, the substrate support 110 is symmetric along its rotational axis A, and circular-shaped from above, enabling a uniform chemical flow into the chemical exit space 150 over the top edge of the substrate support 110. The substrate 130 is placed on the said circular top surface of the substrate support 110 for surface reactions. In certain embodiments, the substrate support 110 is asymmetric around its rotational axis A, to balance the distribution of chemical flow arriving at the substrate processing space 50 and exiting into the chemical exit space 150, when the chemical flow arriving on the substrate is unequally distributed in the first place.

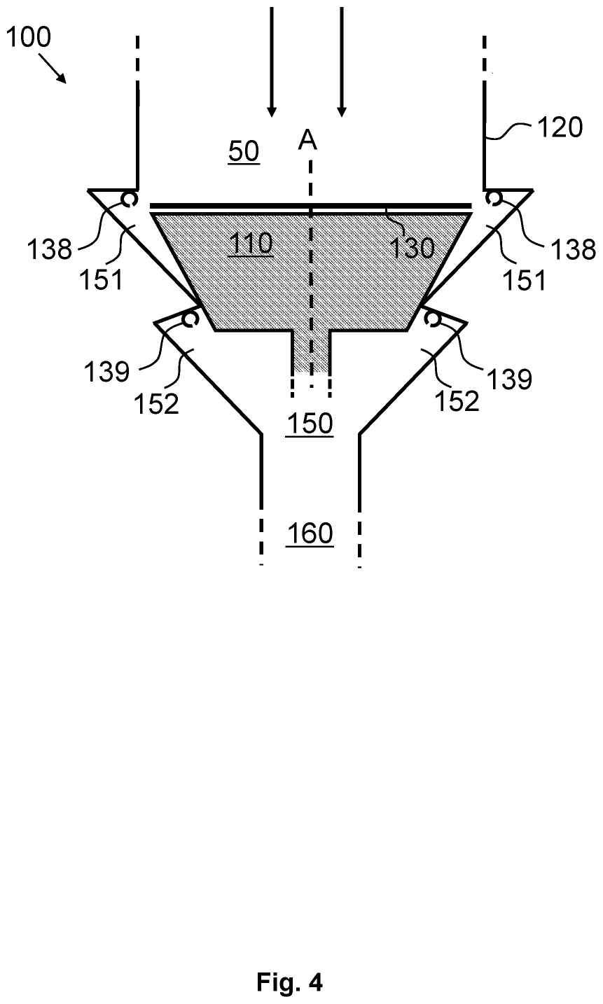

In certain embodiments, the substrate support 110, as depicted in FIGS. 1-4, is vertically adjustable, to facilitate the loading/unloading of the substrate 130 into/from the substrate processing space 50, or to adjust the gaps 126 and 127. In certain embodiments, the loading/unloading of the substrate is facilitated with adjustable lifter pins (not shown) arising from the substrate support 110. The vertical position of the substrate support 110 may be adjusted with the base part of the substrate support. A further technical effect of the vertically adjustable substrate support 110 in certain embodiments, is that it can cut off the chemical flow connection between the substrate processing space 50 and the chemical exit space 150, when the position of the substrate support 110 is vertically adjusted tightly against the reaction chamber 120 inner wall as depicted in FIG. 4. During the substrate processing, the substrate support 110 is positioned as depicted in FIGS. 1-3. The substrate 130 in certain embodiments is a planar substrate or a wafer.

In the apparatus 100 shown in FIGS. 1-3 the chemical flow arriving into the substrate processing space 50 flows towards the substrate 130, for inducing surface reactions on the substrate 130. From the substrate processing space 50, the chemical flow enters through the first gap 126 into the first expansion volume 151, and from there via the second gap 127 into the second expansion volume 152, and from there onwards, towards the reaction chamber outlet channel 160. In certain embodiments, the apparatus 100 may have more than two expansion volumes, which are separated by more than two narrow gaps and which are optionally equipped with more than two circular chemical feed inlets, to further promote a turbulent-free chemical flow. In certain embodiments, the chemical exit space 150 has an opening for chemical outlet 160 residing in a bottom part of the chemical exit space 150, through which the chemicals are exhausted. In certain embodiments, the opening for chemical outlet 160 is at the bottom of the bottom part or on a side of the bottom part. In certain embodiments, the opening for chemical outlet 160 resides symmetrically in the center of the bottom of the bottom part.

In certain embodiments, the apparatus 100 shown in the preceding figures is configured to provide the chemical flow with a choked flow effect in at least one of the gaps 126, 127. In certain embodiments, at least the first gap 126 enables the chemical flow through the gap with a choked flow effect. In certain other embodiments, both gaps 126 and 127 enable a chemical flow with a choked flow effect. When choked flow takes place, the velocity of the chemicals is increased at the passing of the chemical flow through a constricted area. The choked flow occurs when compressed gas flow velocity reaches sonic conditions (Mach 1). In certain embodiments, possible pressure changes/reduction downstream from the gap with a choked flow effect no longer influence the mass flow rate in the system. The choked flow prevents backflow of chemicals in the system by preventing chemicals returning upstream from the choked flow point. In certain embodiments, a chemical flow with a choked flow effect is established in the at least one gap 126, 127 by having an aspect ratio of at least 2:1 (expansion volume width: gap width) in the choked flow point, slightly depending on prevailing process conditions.

FIG. 4 shows a schematic drawing of the reaction chamber 120, with the substrate support 110 vertically adjusted lower. In certain embodiments, vertical adjustment of the substrate support 110 can induce plurality of alterations in the flow conditions and in the structure of the chemical flow route in the reaction chamber 120. Changes in the width of the gaps 126, 127, followed by pressure alterations in the reaction chamber 120 compartments can be achieved. In certain embodiments, vertical adjustment of the substrate support 110 prevents the chemical flow into the reaction chamber outlet channel (or chemical outlet) 160 entirely.

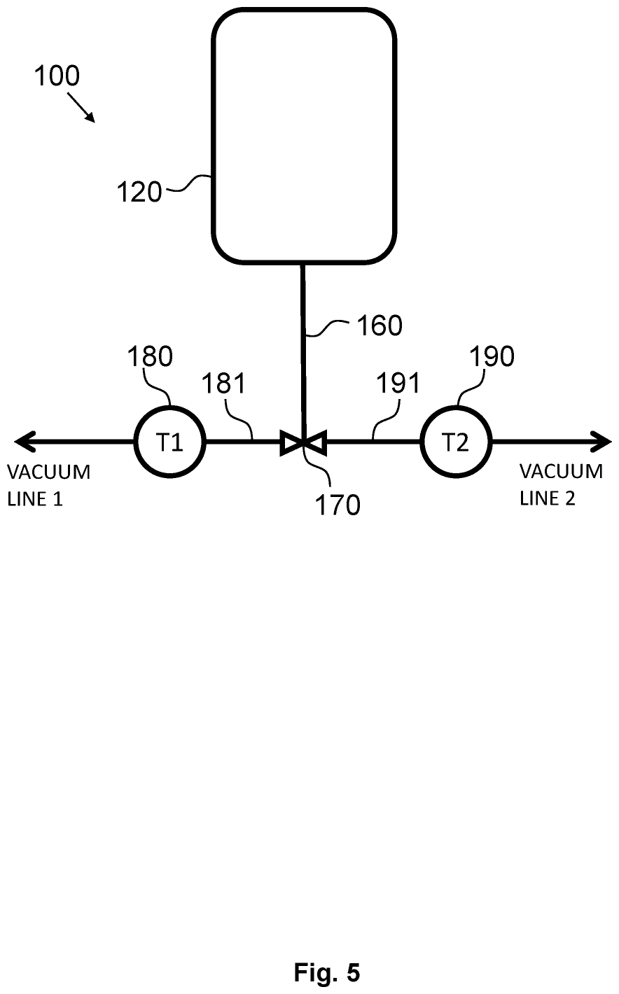

FIG. 5 shows a schematic drawing of the reaction chamber 120 and the chemical outlet 160 line arrangement in accordance with certain embodiments. The reaction chamber 120 is configured to direct the chemical exhaust into the chemical outlet 160, below the reaction chamber 120 (or at least below the substrate processing space 50). The chemical outlet 160 may be divided into two separate branches 181, 191, and a valve 170, positioned in the outlet channel 160, may be used to direct the exhaust into these two separate branches 181, 191 of the chemical outlet 160. The valve 170 may for example be, but is not limited to, a butterfly valve, a 3-way valve or a gate valve. In certain embodiments, the two additional pumps 180, 190 are located in the respective chemical outlet branches 181 and 191. In certain embodiments, the pumps 180 and 190 are turbomolecular pumps. These two (turbomolecular) pumps 180, 190 contribute to creating vacuum conditions in the reaction chamber 120 and exhausting the chemicals from the reaction chamber 120. The valve 170 may be used to separate different chemicals into separate branches 181, 191 of the outlet channel 160, thereby preventing unwanted film growth in the turbomolecular pumps 180, 190. In certain embodiments, the valve 170 directs chemicals from the reaction chamber 120 into the branch 181 of the outlet channel 160 during the pulse of a first precursor chemical. In certain embodiments, the valve 170 directs chemicals from the reaction chamber 120 into the branch 191 of the outlet channel 160 during the pulse of another precursor chemical.

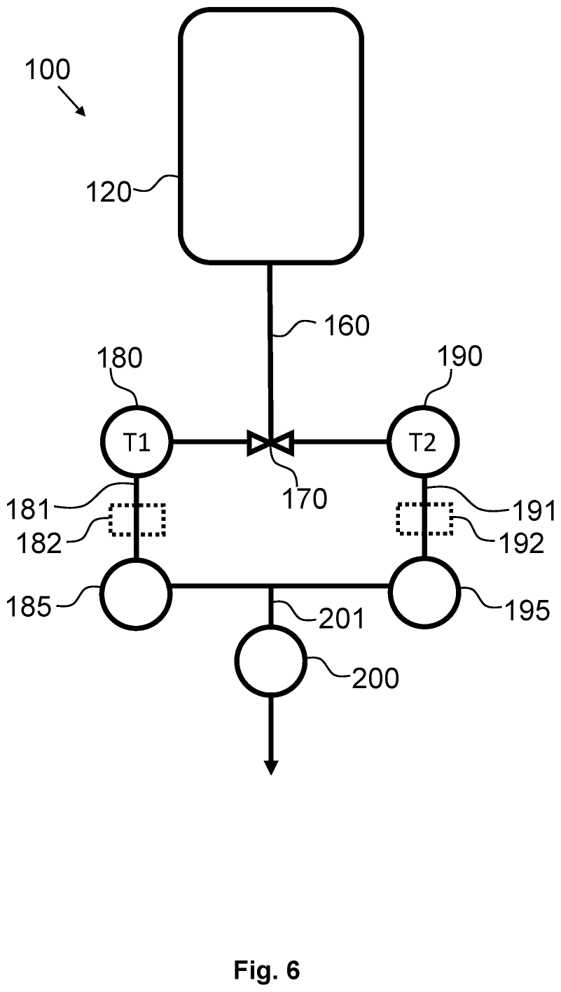

FIG. 6 shows a further schematic drawing of a chemical outlet 160 line arrangement in accordance with certain embodiments. In certain embodiments, at least one chemical trap 182, 192 is optionally placed downstream from the (turbomolecular) pumps 180, 190 in the respective separate branches 181, 191 of the chemical outlet 160. In certain embodiments, the at least one trap 182, 192 may be replaced by a chemical recovery unit. The at least one trap 182, 192 captures unreacted chemical precursor chemicals arriving upstream from the chemical outlet line 160, thereby preventing unwanted deposition on the surfaces of the apparatus 100 downstream from the trap. In certain embodiments, to complement the function of the two pumps 180, 190 and the vacuum conditions maintained in the system, further vacuum pumps 185, 195 may be placed downstream from the said two pumps 180, 190. In certain embodiments, additional traps and/or afterburners may be placed upstream or downstream from the vacuum pumps 185, 195, for additional prevention of unwanted deposition. The two separate branches 181, 191 of the chemical outlet 160, may be united as one common exhaust line 201 leading to ambient, or atmospheric, pressure. The said common exhaust line 201 combines and mixes the chemical flow arriving from the two separate branches 181, 191 of the chemical outlet. A choked flow restrictor enabling chemical flow with a choked flow effect may be integrated into the common exhaust line 201, for improving the flow of chemicals downstream and out of the common exhaust line 201. In certain embodiments, the said choked flow restrictor may replace the pumps 185, 195. A further discharge (or exhaust) pump 200, may be placed in the common exhaust line 201 close to atmospheric pressure, to induce removal of chemicals. Further additional traps and/or after burners may be placed upstream from the pump 200, for additional prevention of unwanted deposition.

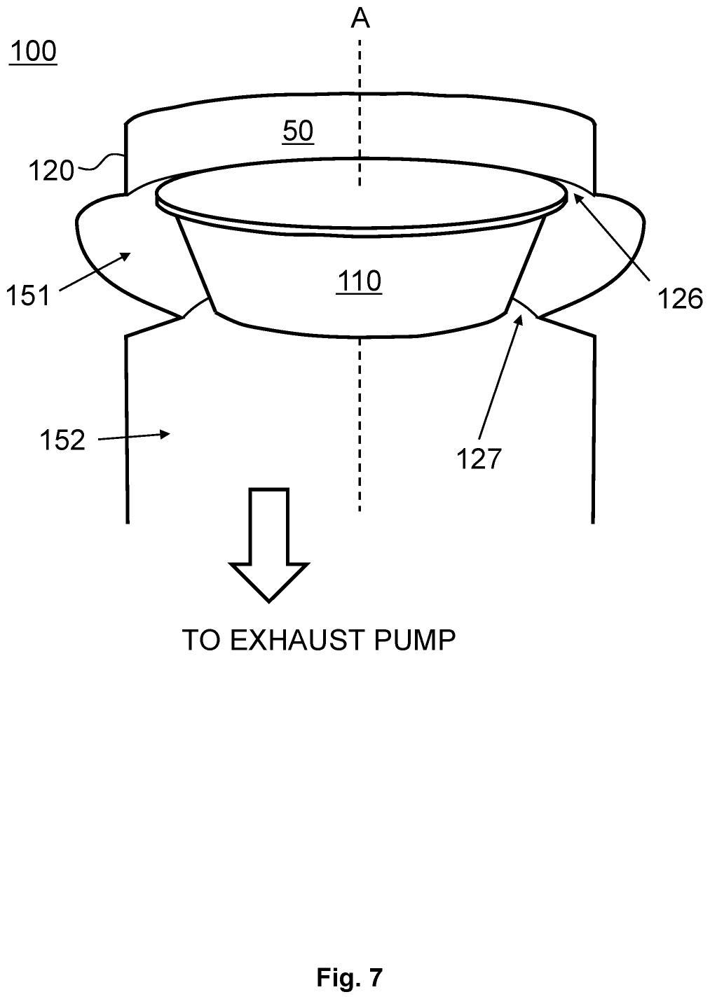

FIG. 7 shows a perspective view of certain parts of the apparatus 100 in accordance with certain embodiments. The reaction chamber 120 encloses the substrate processing space 50 and the chemical exit space (herein formed of volumes 151 and 152). The chemical flow is directed (e.g., inlet from above the substrate, not shown, supported by the substrate support 110) into the substrate processing space 50 to expose the substrate to surface reactions. The chemical flow further flows via the first gap 126 into the first expansion volume 151 of the chemical exit space, and therefrom via the second gap 127 towards an appropriate exhaust pump (not shown). The apparatus is configured to provide the chemical flow with a choked flow effect in at least one of the first and second gaps 126, 127. The edges of the first expansion volume 151 have been rounded to prevent turbulence, as an example.

Without limiting the scope and interpretation of the patent claims, certain technical effects of one or more of the example embodiments disclosed herein are listed in the following. A technical effect is preventing the backflow of chemicals or particles downstream of the substrate. A further technical effect is enabling the loading and unloading of the substrate into and from the substrate processing space, without a need to alter the pressure in the chemical outlet, due to the restricted flow of gases. A further technical effect is that by lowering the substrate support, valves closing the chemical outlet can be omitted. Typically, the valves for this purpose collect unwanted growth and particles from the deposition reaction, and due to this, often eventually become leaky. Hence, a structure without a valve closing the chemical outlet 160 may be better protected from leakiness. A further technical effect is significantly reducing or omitting the number of traps, afterburners or scrubbers, which would conventionally be used in an ALD or CVD reactor. A further technical effect is prevention of particles generated by valve(s) in the reaction chamber outlet channel (e.g., valve 170 described in the preceding) from entering the substrate processing space 50, due to choked flow in the gap(s).

The foregoing description has provided by way of non-limiting examples of particular implementations and embodiments of the present disclosure a full and informative description of the best mode presently contemplated by the inventors for carrying out the disclosed embodiments. It is however clear to a person skilled in the art that the disclosed embodiments is not restricted to details of the embodiments presented above, but that it can be implemented in other embodiments using equivalent means without deviating from the characteristics of the disclosed embodiments.

Furthermore, some of the features of the above-disclosed embodiments of this present disclosure may be used to advantage without the corresponding use of other features. As such, the foregoing description should be considered as merely illustrative of the principles of the present disclosure, and not in limitation thereof. Hence, the scope of the disclosed embodiments is only restricted by the appended patent claims.

1. A substrate processing apparatus, comprising:
a reaction chamber, enclosing a substrate processing space and a chemical exit space; and
a substrate support;
the apparatus being configured to direct a chemical flow into the substrate processing space, to expose a substrate supported by the substrate support to surface reactions, therefrom via a first gap into a first expansion volume of the chemical exit space, and therefrom via a second gap towards an exhaust pump, the apparatus being configured to provide the chemical flow with a choked flow effect in at least one of the first and second gaps.

2. The apparatus of claim 1, where the chemical exit space comprises a second expansion volume, the apparatus being configured to direct the chemical flow from the first expansion volume via the second gap into the second expansion volume.

3. The apparatus of claim 1, configured to remove the chemical flow from the reaction chamber into a reaction chamber outlet channel.

4. The apparatus of claim 1, wherein the substrate support is rotationally symmetric about its rotational axis.

5. The apparatus of claim 1, wherein the vertical position of the substrate support is adjustable.

6. The apparatus of claim 1, wherein
the apparatus is configured to provide a chemical flow route into a volume in between the substrate support and an inner surface of the reaction chamber, the inner surface of the reaction chamber and the substrate support delimiting a space forming at least one of the expanding volumes.

7. The apparatus of claim 1, wherein at least one of the gaps is formed in between the substrate support and the reaction chamber inner surface.

8. The apparatus of claim 1, wherein the first gap is configured to provide the chemical flow with a choked flow effect.

9. The apparatus of claim 1, wherein both, first and second gaps are configured to provide the chemical flow with a choked flow effect.

10. The apparatus of claim 1, comprising at least one circular chemical feed inlet configured to inject inert and/or reactive chemical into the chemical exit space.

11. The apparatus of claim 10, comprising the at least one chemical feed inlet, arranged immediately downstream from one of the said gaps, to prevent backflow of chemicals in the chemical exit space.

12. The apparatus of claim 1, where a reaction chamber outlet channel comprises two separate branches, the apparatus comprising a pump in each two separate branches of the outlet channel, to exhaust gases from the reaction chamber.

13. The apparatus of claim 12, comprising a valve in the outlet channel, configured to control flow of chemicals into the two separate branches.

14. The apparatus of claim 12, comprising a vacuum pump in one of the separate branches of the outlet channel, downstream from the two pumps, or comprising a vacuum pump in each separate branch of the outlet channel, downstream from the respective pump.

15. The apparatus of claim 1, wherein the substrate support is arranged to cut off the chemical flow towards the exhaust pump.

16. A method in a substrate processing apparatus having a reaction chamber enclosing a substrate processing space and a chemical exit space, comprising:
directing a chemical flow into the substrate processing space, to expose a substrate supported by a substrate support to surface reactions;
directing the chemical flow therefrom via a first gap into a first expansion volume of the chemical exit space, and therefrom via a second gap towards an exhaust pump; and
providing the chemical flow with a choked flow effect in at least one of the first and second gaps.
